(19) United States
(12) Patent Application Publication
(10) Pub. No.: US 2026/0114266 A1
(43) Pub. Date: Apr. 23, 2026

(54) CONDUCTIVE WIRES, INTERCONNECT STRUCTURES AND INTEGRATED CIRCUIT DEVICES

(71) Applicant: SAMSUNG ELECTRONICS CO., LTD., Suwon-si (KR)

(72) Inventors: Yu jin Han, Suwon-si (KR); Keun Wook SHIN, Suwon-si (KR); GIYOUNG JO, Suwon-si (KR); Daejin YANG, Suwon-si (KR); JEONGYUB LEE, Suwon-si (KR)

(21) Appl. No.: 19/286,815

(22) Filed: Jul. 31, 2025

(30) Foreign Application Priority Data
Oct. 22, 2024 (KR) 10-2024-0144908

(51) Int. Cl. H01L 23/532

(52) U.S. Cl. CPC H10W 20/4446; H10W 20/425; H10W 20/48

(57) ABSTRACT

Embodiments provide a conductive wire, an interconnect structure including the conductive wire, and an integrated circuit device including the interconnect structure. The conductive wire has a line width of equal to or greater than about 1 nm and less than about 10 nm and including a molybdenum-tungsten alloy. The interconnect structure includes one or more dielectric layers and the conductive wire adjacent to the dielectric layers,

### CROSS-REFERENCE TO RELATED APPLICATION

This application claims priority to Korean Patent Application No. 10-2024-0144908, filed on Oct. 22, 2024, and all the benefits accruing therefrom under 35 U.S.C. § 119, the content of which in its entirety is herein incorporated by reference.

### BACKGROUND

### 1. Field

Conductive wires, interconnect structures, and integrated circuit devices are disclosed.

### 2. Description of the Related Art

In order to provide highly integrated, high-performance integrated circuit devices, technologies for reducing dimensions of unit devices that constitute integrated circuit devices are being studied, and accordingly, there is a demand to also reduce a line width of the wire that electrically connects the unit devices.

### SUMMARY

However, if the wire width is reduced below a certain range, the resistance may increase rapidly due to material limitations, which may deteriorate the electrical characteristics.

An embodiment provides a conductive wire that may reduce or prevent degradation of electrical characteristics even at reduced line width.

Another embodiment provides an interconnect structure including the conductive wire.

Another embodiment provides an integrated circuit device including the conductive wire or the interconnect structure.

According to an embodiment, a conductive wire has a line width of less than equal to or greater than about 1 nanometer (nm) and about 10 nm and includes a molybdenum-tungsten alloy (Mo—W alloy).

The conductive wire may have an aspect ratio of a line thickness to the line width of greater than or equal to about 3.

The Mo—W alloy may be represented by Mo₁₋ₓWₓ (0<x≤0.99).

The tungsten included in the Mo—W alloy may be included in an amount of greater than 0 atomic percentage (at %) and less than about 50 at % based on a total number of atoms of the molybdenum (Mo) and the tungsten (W) included in the molybdenum-tungsten alloy.

For line widths of less than about 10 nm, a change in resistivity of the conductive wire according to a 10% decrease in line width may be less than about twice (i.e., less than about 20%).

A resistivity of the conductive wire may be less than or equal to about 30 microhm-centimeters (μΩ·cm).

According to another embodiment, an interconnect structure includes one or more dielectric layers, and a conductive wire adjacent to the dielectric layers, wherein the conductive wire has a line width of equal to or greater than about 1 nm and less than 10 nm and including a Mo—W alloy.

The dielectric layer may define therein a trench, and the conductive wire may be disposed in the trench.

The conductive wire may have an aspect ratio of a line thickness to the line width of greater than or equal to about 3.

The Mo—W alloy may be represented by Mo₁₋ₓWₓ (0<x≤0.99).

The tungsten included in the Mo—W alloy may be included in an amount of greater than 0 at % and less than about 50 at % based on a total number of atoms of the molybdenum (Mo) and the tungsten (W) included in the molybdenum-tungsten alloy.

A change in a resistivity of the conductive wire according to a 10% decrease in the line width of less than 10 nm may be less than about twice (i.e., less than 20%), and the resistivity of the conductive wire may be less than or equal to about 30μΩ·cm.

The dielectric layer may include a metal oxide, a semi-metal oxide, a carbon-doped metal oxide, a carbon-doped semi-metal oxide, a metal carbide, a semi-metal carbide, a hydrogenated metal carbide, a hydrogenated semi-metal carbide, a metal nitride, a semi-metal nitride, a carbon-doped metal nitride, a carbon-doped semi-metal nitride, a metal oxynitride, a semi-metal oxynitride, a carbon-doped metal oxynitride, a carbon-doped semi-metal oxynitride, or a combination thereof.

The conductive wire and the dielectric layer may be in contact with each other.

The interconnect structure may further include an anti-scattering layer disposed on an upper portion of the conductive wire.

The interconnect structure may further include a liner between the dielectric layer and the conductive wire, wherein the liner may include tungsten or a tungsten alloy (excluding a molybdenum-tungsten alloy).

The dielectric layer may include a first dielectric layer and a second dielectric layer positioned at different heights, and the conductive wire may include a first conductive wire disposed in a trench defined in the first dielectric layer and a second conductive wire disposed in a trench defined in the second dielectric layer.

According to another embodiment, an integrated circuit device including the conductive wire or the interconnect structure is provided.

The integrated circuit device may further include a transistor, a capacitor, a diode, a resistor, or a combination thereof, electrically connected to the conductive wire.

A material limitation may be overcome and deterioration of electrical characteristics in fine wire of less than about 10 nm may be effectively reduced or prevented.

### BRIEF DESCRIPTION OF THE DRAWINGS

FIG. 1 is a cross-sectional view showing an example of an interconnect structure according to an embodiment,

FIG. 2 is a cross-sectional view showing another example of an interconnect structure according to an embodiment,

FIGS. 3 to 5 are cross-sectional views showing another example of an interconnect structure according to an embodiment,

FIG. 6 is a cross-sectional view showing another example of an interconnect structure according to an embodiment,

FIGS. 7 to 11 are cross-sectional views showing another example of an interconnect structure according to an embodiment,

FIG. 12 is a cross-sectional view showing another example of an interconnect structure according to an embodiment,

FIG. 13 is a plan view showing an example of an integrated circuit device according to an embodiment,

FIG. 14 is a perspective view showing an example of the integrated circuit device of FIG. 13,

FIG. 15 is a schematic view showing an example of a transistor of the integrated circuit device of FIG. 13,

FIG. 16 is a conceptual view showing an example of an electronic device according to an embodiment,

FIG. 17 is a graph showing the resistivity according to the line width of Mo—W alloy wire and copper wire,

FIG. 18 shows XRD graphs for the Mo—W alloy wires according to Examples 1-1 to 1-3, and

FIG. 19 shows XRD graphs for the Mo—W alloy wires according to Examples 2-1 to 2-3.

### DETAILED DESCRIPTION

Hereinafter, the embodiments will be described in detail so that those of ordinary skill in the art may easily implement them. However, the actually applied structure may be implemented in several different forms and is not limited to the embodiments described herein.

The terminology used herein is used to describe embodiments only, and is not intended to limit the present disclosure. The singular expression includes the plural expression unless the context clearly dictates otherwise.

Here, it should be understood that terms such as “comprises,” “includes,” or “have” are intended to designate the presence of an embodied feature, number, step, element, or a combination thereof, but it does not preclude the possibility of the presence or addition of one or more other features, number, step, element, or a combination thereof.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

The drawings and description are to be regarded as illustrative in nature and not restrictive. Like reference numerals designate like elements throughout the specification.

It will be understood that when a component is referred to as being “on” or “above” another component, the component can be directly on, under, on the left of, or on the right of the other component, or can be on, under, on the left of, or on the right of the other component in a non-contact manner. In addition, unless explicitly described to the contrary, the word “comprise,” and variations such as “comprises” or “comprising,” will be understood to imply the inclusion of stated elements.

The term “layer” includes a construction having a shape formed on a part of a region, in addition to a construction having a shape formed on an entire region.

As used herein, the term “the” or similar indicative terms correspond to both the singular form and the plural form. The steps of all methods described herein can be performed in any suitable order unless otherwise indicated herein or otherwise clearly contradicted by context.

Here, “combination thereof” refer to a mixture, a stacked structure, a composite, an alloy, or a blend of constituents.

Hereinafter, unless otherwise defined, “substantially” or “approximately” or “about” includes not only the stated value, but also the average within an allowable range of deviation, considering the error associated with the measurement and amount of the measurement. For example, “substantially” or “about” may mean within ±10%, ±5%, ±3%, or ±1% of the indicated value or within a standard deviation.

Hereinafter, “metal” includes metals and metalloids (semi-metals).

An example of a conductive wire according to an embodiment is described.

The conductive wire according to an embodiment may include any wire that transmits an electrical signal or requires an electrical connection, and for example, in an integrated circuit device, may include any wire that electrically connects between active devices, between passive devices, and/or between an active device and a passive device.

The conductive wire may be a three-dimensional structure having a width, a length and a thickness, wherein the longitudinal direction of the conductive wire may be a direction in which electrons move and may be a direction perpendicular to the width direction and the thickness direction, respectively.

A line width of the conductive wire may be on the nanometer level, for example, less than about 10 nanometers (nm), less than or equal to about 9 nm, less than or equal to about 8 nm, less than or equal to about 7 nm, less than or equal to about 6 nm, less than or equal to about 5 nm, less than or equal to about 4 nm, less than or equal to about 3 nm, greater than or equal to about 1 nm and less than 10 nm, about 1 nm to about 9 nm, about 1 nm to about 8 nm, about 1 nm to about 7 nm, about 1 nm to about 6 nm, about 1 nm to about 5 nm, about 1 nm to about 4 nm, or about 1 nm to about 3 nm.

The conductive wire may have a high aspect ratio, where the aspect ratio may be a ratio of height or thickness to width of the conductive wire. The aspect ratio of the conductive wire may be greater than or equal to about 3, and within the range of about 3 to about 50, about 3 to about 45, about 3 to about 40, about 3 to about 35, about 3 to about 30, about 5 to about 50, about 5 to about 45, about 5 to about 40, about 5 to about 35, or about 5 to about 30. The conductive wire may be a narrow-width wire having a high aspect ratio in the above range. That is, the width of the conductive wire may be smaller than the height or thickness thereof.

The conductive wire may include a molybdenum (Mo)-based multi-component alloy, for example a Mo-based binary alloy or ternary alloy.

For example, the conductive wire may include an alloy including molybdenum (Mo) and tungsten (W) (hereinafter referred to as a ‘molybdenum-tungsten alloy’ or ‘Mo—W alloy’). In an embodiment, the conductive wire may include only molybdenum (Mo) and tungsten (W), and may not include any other metal material. Unlike common bulk metals such as copper (Cu), the Mo—W alloy may exhibit high reliability without a rapid increase in resistance in conductive wire with the aforementioned nanometer-level fine line widths.

Specifically, Mo is a metal having relatively low resistivity and may be a base material for forming an alloy, and a Mo—W alloy including a predetermined content of W in Mo may effectively reduce electron scattering at the surface and grain boundaries in a conductive wire having a fine line width of the nanometers by reducing the electron mean free path (eMFP), thereby effectively reducing or preventing a rapid increase in the resistance of the conductive wire having a fine line width of the nanometers. The value multiplied by the resistivity (bulk resistivity) of a metal and the electron mean free path may be an indicator for predicting the increase in resistivity in conductive wire with a fine line width at the nanometer level, and the smaller the value multiplied by the resistivity (bulk resistivity) of a metal and the electron mean free path, the lower the rate of increase in resistivity of conductive wire with a fine line width may be expected.

In addition, the tungsten (W) is a metal with relatively high cohesive energy, which may reduce the drift of metal ions due to charging current or the diffusion or stress gradient of atoms due to heat, thereby increasing the reliability of conductive wire. Accordingly, the conductive wire including the Mo—W alloy may reduce or prevent diffusion of metal from the conductive wire to an adjacent layer (e.g., a dielectric layer) without an additional barrier layer, and may effectively prevent space loss and loss of electrical properties of the conductive wire due to the barrier layer.

In addition, these molybdenum (Mo) and tungsten (W) may form a substantially uniform alloy with high crystallinity without phase separation by having an alloy formation energy (Et) less than 0 in all composition ratios of molybdenum (Mo) and tungsten (W) (wherein, Mo is greater than 0 at % and less than 100 at % and W is greater than 0 at % and less than 100 at % based on a total number of atoms of the molybdenum and the tungsten included in the molybdenum-tungsten alloy).

In this way, molybdenum (Mo) and tungsten (W) may be effectively alloyed by considering resistivity, electron mean free path, and cohesive energy, and the Mo—W alloy may be applied to conductive wire with a fine line width of less than about 10 nm to simultaneously satisfy conductivity and reliability.

For example, in a conductive wire having a fine line width of less than about 10 nm, the change in resistivity of the conductive wire due to a 10% decrease in line width may be less than about twice (e.g., less than 20% increase in the resistivity) of the change of the line width. Within the above range, the change in resistivity of the conductive wire due to a 10% decrease in line width may be about 1 to 1.8 times, about 1 to 1.6 times, or about 1 to 1.4 times.

For example, in a conductive wire having a fine line width of less than about 10 nm, the resistivity of the conductive wire may be less than or equal to about 30 microhm-centimeters (μΩ·cm). Within the above range, the resistivity of the conductive wire may be less than or equal to about 28 μΩ·cm, less than or equal to about 26 μΩ·cm, or less than or equal to about 25 μΩ·cm, and within the above range about 2 μΩ·cm to about 30μΩ·cm, about 2μΩ·cm to about 28μΩ·cm, about 2μΩ·cm to about 26μΩ·cm, about 2μΩ·cm to about 25μΩ·cm, about 5μΩ·cm to about 30μΩ·cm, about 5μΩ·cm to about 28 μΩ·cm, about 5μΩ·cm to about 26μΩ·cm, about 5μΩ·cm to about 25μΩ·cm, about 10μΩ·cm to about 30μΩ·cm, about 10μΩ·cm to about 28μΩ·cm, about 10μΩ·cm to about 26μΩ·cm, or about 10μΩ·cm to about 25μΩ·cm.

A composition ratio between molybdenum (Mo) and tungsten (W) in the Mo—W alloy may be determined within a range that satisfies the aforementioned conductivity and reliability.

For example, in the Mo—W alloy, molybdenum (Mo) may be included in greater amounts than tungsten (W), and tungsten (W) may be included in amounts less than about 50 at % based on a total number of atoms of molybdenum (Mo) and tungsten (W) included in the alloy. Within the above range, tungsten (W) may be included in an amount of greater than 0 at % and less than or equal to about 45 at %, greater than 0 at % and less than or equal to about 40 at %, greater than 0 at % and less than or equal to about 35 at %, greater than 0 at % and less than or equal to about 30 at %, greater than 0 at % and less than or equal to about 25 at %, greater than 0 at % and less than or equal to about 20 at %, greater than 0 at % and less than or equal to about 15 at %, greater than 0 at % and less than or equal to about 10 at %, about 2 at % to about 45 at %, about 2 at % to about 40 at %, about 2 at % to about 35 at %, about 2 at % to about 30 at %, about 2 at % to about 25 at %, about 2 at % to about 20 at %, about 2 at % to about 15 at %, or about 2 at % to about 10 at %, based on the total number of atoms of molybdenum (Mo) and tungsten (W) included in the alloy.

For example, in the Mo—W alloy, tungsten (W) may be included in an amount equal to or greater than molybdenum (Mo), and tungsten (W) may be included in an amount of greater than or equal to about 50 at % based on the total number of atoms of molybdenum (Mo) and tungsten (W) included in the Mo—W alloy. Within the above range, tungsten (W) may be included in the alloy in an amount of about 50 at % to about 99.9 at %, about 50 at % to about 95 at %, about 50 at % to about 90 at %, about 50 at % to about 85 at %, about 50 at % to about 80 at %, about 50 at % to about 75 at %, about 50 at % to about 70 at %, about 55 at % to about 99.9 at %, about 55 at % to about 95 at %, about 55 at % to about 90 at %, about 55 at % to about 85 at %, about 55 at % to about 80 at %, about 55 at % to about 75 at %, about 55 at % to about 70 at %, about 60 at % to about 99.9 at %, about 60 at % to about 95 at %, about 60 at % to 90 at %, about 60 at % to about 85 at %, about 60 at % to about 80 at %, about 60 at % to about 75 at %, or about 60 at % to about 70 at %.

For example, the Mo—W alloy may further include one or more other metal atoms and/or non-metal atoms, in addition to molybdenum (Mo) and tungsten (W), and the additionally included metal atoms and/or non-metal atoms may be included in an amount less than molybdenum (Mo) or tungsten (W). For example, the Mo—W alloy may not additionally include niobium (Nb).

For example, the Mo—W alloy may be composed of molybdenum (Mo) and tungsten (W) as metal atoms, and may not include additional metal atoms other than molybdenum (Mo) and tungsten (W).

For example, the Mo—W alloy may be represented by Mo₁₋ₓWₓ, wherein x may be in the range of 0<x<0.99, 0<x≤0.95, 0<x≤0.90, 0<x≤0.85, 0<x≤0.80, 0<x≤0.75, 0<x≤0.70, 0<x≤0.60, 0<x≤0.50, 0<x≤0.45, 0<x≤0.40, 0<x≤0.35, 0<x≤0.30, 0<x≤0.25, 0<x≤0.20, 0<x≤0.15, or 0<x≤0.10.

For example, the Mo—W alloy may be represented by Mo₁₋ₓWₓ, wherein x may be in the range of 0<x<0.50, 0<x≤0.45, 0<x≤0.40, 0<x≤0.35, 0<x≤0.30, 0<x≤0.25, 0<x≤0.20, 0<x≤0.15, 0<x≤0.10, 0<x≤0.08, 0.02≤x<0.50, 0.02≤x≤0.45, 0.02≤x≤0.40, 0.02≤x≤0.35, 0.02≤x≤0.30, 0.02≤x≤0.25, 0.02≤x≤0.20, 0.02≤x≤0.15, 0.02≤x≤0.10, 0.02≤x≤0.08, 0.03≤x<0.50, 0.03≤x≤0.45, 0.03≤x≤0.40, 0.03≤x≤0.35, 0.03≤x≤0.30, 0.03≤x≤0.25, 0.03≤x≤0.20, 0.03≤x≤0.15, 0.03≤x≤0.10, 0.03≤x≤0.08, 0.05≤x<0.50, 0.05≤x≤0.45, 0.05≤x≤0.40, 0.05≤x≤0.35, 0.05≤x≤0.30, 0.05≤x≤0.25, 0.05≤x≤0.20, 0.05≤x≤0.15, 0.05≤x≤0.10, or 0.05≤x≤0.08. For example, x may be in the range of 0<x≤0.15, 0<x≤0.10, 0<x≤0.08, 0.02≤x≤0.15, 0.02≤x≤0.10, 0.02≤x≤0.08, 0.03≤x≤0.15, 0.03≤x≤0.10, 0.03≤x≤0.08, 0.05≤x≤0.15, 0.05≤x≤0.10, or 0.05≤x≤0.08.

For example, the Mo—W alloy may be represented by Mo₁₋ₓWₓ, wherein x may be in the range of 0.50≤x≤0.99, 0.50≤x≤0.90, 0.50≤x<0.85, 0.50≤x≤0.80, 0.50≤x≤0.75, 0.50≤x≤0.70, 0.55≤x≤0.99, 0.55≤x≤0.90, 0.55≤x<0.85, 0.55≤x≤0.80, 0.55≤x≤0.75, 0.55≤x≤0.70, 0.60≤x≤0.99, 0.60≤x≤0.90, 0.60≤x<0.85, 0.60≤x≤0.80, 0.60≤x≤0.75, or 0.60≤x≤0.70.

The aforementioned conductive wire may extend horizontally and/or vertically on a substrate (not shown) and may be embedded in or disposed adjacent to a trench of a dielectric layer to form an interconnect structure that electrically connects one or more devices.

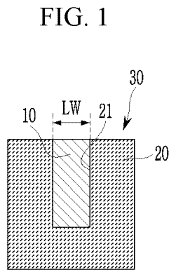

FIG. 1 is a cross-sectional view showing an example of an interconnect structure according to an embodiment.

Referring to FIG. 1, an interconnect structure 30 according to an embodiment includes a dielectric layer 20 and a conductive wire 10.

A substrate (not shown) may be disposed under the dielectric layer 20, and the substrate may be a semiconductor substrate. The semiconductor substrate may include, for example, a Group IV semiconductor material, a Group III-V semiconductor compound, or a Group II-VI semiconductor compound, for example, a Group IV semiconductor material including at least one or more of Si, Ge, Sn, and C, a Group III-V compound semiconductor material in which at least one or more of B, Ga, In, and Al are combined with at least one or more of N, P, As, Sb, S, Se, and Te, or a Group II-VI compound semiconductor material in which at least one or more of Be, Mg, Cd, and Zn are combined with at least one or more of O, S, Se, and Te. For example, the semiconductor substrate may include Si, Ge, SiC, SiGe, SiGeC, Ge alloy, GaAs, InAs, InP, and the like, but is not limited thereto.

The substrate may include at least one semiconductor device (not shown) in and/or on the substrate, for example at least one of a transistor, a capacitor, a diode, or a resistor, but is not limited thereto.

The dielectric layer 20 may include for example, a dielectric material having a dielectric constant of less than or equal to about 4.0, for example, a metal oxide, a semi-metal oxide, a carbon-doped metal oxide, a carbon-doped semi-metal oxide, a metal carbide, a semi-metal carbide, a hydrogenated metal carbide, a hydrogenated semi-metal carbide, a metal nitride, a semi-metal nitride, a carbon-doped metal nitride, a carbon-doped semi-metal nitride, a metal oxynitride, a semi-metal oxynitride, a carbon-doped metal oxynitride, a carbon-doped semi-metal oxynitride, or a combination thereof. The dielectric layer 20 may include, for example, AlO_{z} (0<z≤3/2, for example, Al₂O₃), AlN, ZrOₓ (0<x≤2), HfOₓ (0<x≤2), SiO₂, SiCO, SiCN, SiON, SiCOH, AlSiO, BN (Boron Nitride), or a combination thereof, but is not limited thereto. In an embodiment, the dielectric layer 20 may not include a molybdenum-tungsten alloy.

The dielectric layer 20 may define therein one or more trenches 21.

The trench 21 may have a narrow width and may have a width of less than about 10 nm, like the width LW of the aforementioned conductive wire. A width of the trench 21 may be, for example, within the above range, less than or equal to about 9 nm, less than or equal to about 8 nm, less than or equal to about 7 nm, less than or equal to about 6 nm, less than or equal to about 5 nm, less than or equal to about 4 nm, less than or equal to about 3 nm, less than or equal to about 1 nm and less than about 10 nm, about 1 nm to about 9 nm, about 1 nm to about 8 nm, about 1 nm to about 7 nm, about 1 nm to about 6 nm, about 1 nm to about 5 nm, about 1 nm to about 4 nm, or about 1 nm to about 3 nm.

The trench 21 may have a high aspect ratio, where the aspect ratio may be a ratio of depth to width of the trench 21. The aspect ratio of the trench 21 may be substantially the same as the aspect ratio of the conductive wire 10, may be greater than or equal to about 3, and within the above range, may be about 3 to about 50, about 3 to about 45, about 3 to about 40, about 3 to about 35, about 3 to about 30, about 5 to about 50, about 5 to about 45, about 5 to about 40, about 5 to about 35, or about 5 to about 30. The trench 21 may be narrow and deep by having a high aspect ratio within the above range.

The conductive wire 10 may be embedded in a trench 21 of the dielectric layer 20. The conductive wire 10 has a line width LW of less than about 10 nm as described above, and may include the Mo—W alloy. A specific description of the conductive wire 10 is as described above. As described above, the conductive wire 10 including the Mo—W alloy may reduce or prevent diffusion of metal from the conductive wire 10 to an adjacent layer (e.g., a dielectric layer 20) without an additional barrier layer, so that the conductive wire 10 may be in direct contact with the wall surface of the dielectric layer 20 in the trench 21, and thus, space loss and electrical characteristic loss of the conductive wire 10 in the trench 21 due to the additional barrier layer may be effectively prevented.

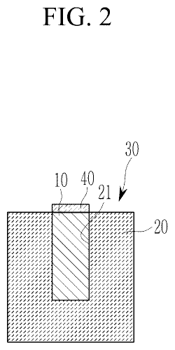

FIG. 2 is a cross-sectional view showing another example of an interconnect structure according to an embodiment.

Referring to FIG. 2, the interconnect structure 30 according to the present example includes a conductive wire 10 and a dielectric layer 20 defining therein a trench 21, like the example described above.

However, unlike the aforementioned example, the interconnect structure 30 according to the present example may further include an anti-scattering layer 40 on the surface of the conductive wire 10. The anti-scattering layer 40 may more effectively reduce electron scattering at the surface of the conductive wire 10. The anti-scattering layer 40 may include a conductor, a semiconductor, and/or an insulator, and may include a metal (e.g., Ti, W, etc.) or a metal alloy, graphene, metal-doped graphene, or a combination thereof, but is not limited thereto. In an embodiment, the anti-scattering layer 40 may not include a molybdenum-tungsten alloy.

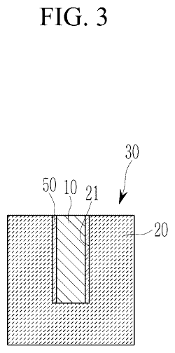

FIGS. 3 to 5 are cross-sectional views showing another example of an interconnect structure according to an embodiment.

Referring to FIGS. 3 to 5, the interconnect structure 30 according to the present example includes a conductive wire 10 and a dielectric layer 20 defining therein a trench 21, like the example described above.

However, unlike the aforementioned example, the interconnect structure 30 according to the present example further includes a liner 50 in at least a portion between the conductive wire 10 and the dielectric layer 20 in the trench 21.

The liner 50 may increase the adhesion between the conductive wire 10 and the dielectric layer 20 in the trench 21. The liner 50 may include a conductor, a semiconductor and/or an insulator, for example, a metal, a metal alloy, a nitride thereof, or a combination thereof, and may be W, Ti, TIN, SiN, an alloy thereof, or a combination thereof, but is not limited thereto. For example, the liner 50 may include tungsten or a tungsten alloy (excluding a molybdenum-tungsten alloy), and thus the conductive wire 10 including the Mo—W alloy and the liner 50 including tungsten or a tungsten alloy may form a continuous interface to have a substantially seamless interface, thereby further enhancing the electrical characteristics of the conductive wire 10.

For example, referring to FIG. 3, the liner 50 may be disposed between the side surface of the conductive wire 10 and the dielectric layer 20.

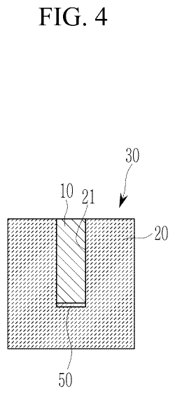

For example, referring to FIG. 4, the liner 50 may be disposed between the lower surface of the conductive wire 10 and the dielectric layer 20.

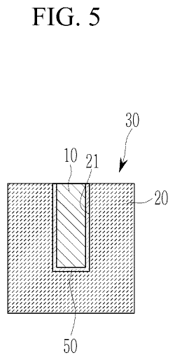

For example, referring to FIG. 5, the liner 50 may be disposed between the side surface and lower surfaces of the conductive wire 10 and the dielectric layer 20.

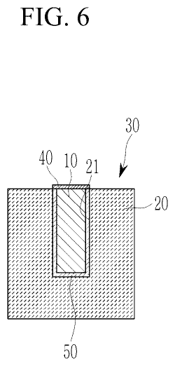

FIG. 6 is a cross-sectional view showing another example of an interconnect structure according to an embodiment.

Referring to FIG. 6, the interconnect structure 30 according to the present example includes a conductive wire 10 and a dielectric layer 20 defining therein a trench 21, like the example described above.

However, unlike the above-described example, the interconnect structure 30 according to the present example may further include an anti-scattering layer 40 on the upper surface of the conductive wire 10 and a liner 50 between the side surfaces and lower surfaces of the conductive wire 10 and the dielectric layer 20. The anti-scattering layer 40 and the liner 50 are as described above, and the anti-scattering layer 40 and the liner 50 may include the same or different materials.

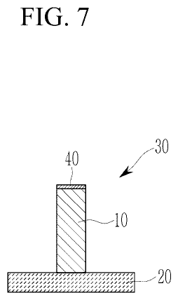

FIGS. 7 to 11 are cross-sectional views showing another example of an interconnect structure according to an embodiment.

Referring to FIGS. 7 to 11, the interconnect structure 30 according to the present example includes a dielectric layer 20 and a conductive wire 10, like the example described above.

However, the interconnect structure 30 according to the present example may have a structure in which the conductive wire 10 is disposed on the dielectric layer 20 and is not embedded in a trench, but is disposed adjacent to the dielectric layer 20, unlike the example described above.

For example, referring to FIG. 7, the conductive wire 10 may be disposed on the dielectric layer 20 and may further include an anti-scattering layer 40 on an upper portion of the conductive wire 10.

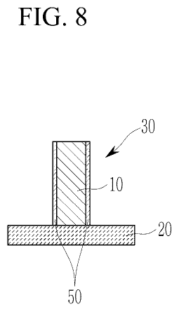

For example, referring to FIG. 8, the conductive wire 10 may be disposed on the dielectric layer 20 and may further include a liner 50 disposed on the side surface of the conductive wire 10.

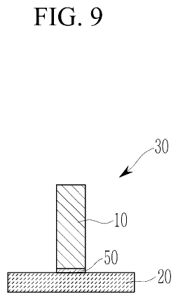

For example, referring to FIG. 9, the conductive wire 10 may be disposed on the dielectric layer 20 and may further include a liner 50 disposed between the lower surface of the conductive wire 10 and the dielectric layer 20.

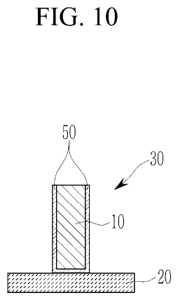

For example, referring to FIG. 10, the conductive wire 10 may be disposed on the dielectric layer 20 and may further include a liner 50 disposed on the side surfaces of the conductive wire 10 and between lower surfaces of the conductive wire 10 and the dielectric layer 20.

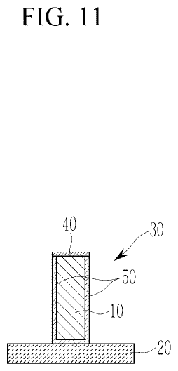

For example, referring to FIG. 11, the conductive wire 10 may be disposed on the dielectric layer 20 and may further include an anti-scattering layer 40 disposed on the upper surface of the conductive wire 10, and a liner 50 disposed on the side surfaces of the conductive wire 10 and between lower surfaces of the conductive wire 10 and the dielectric layer 20.

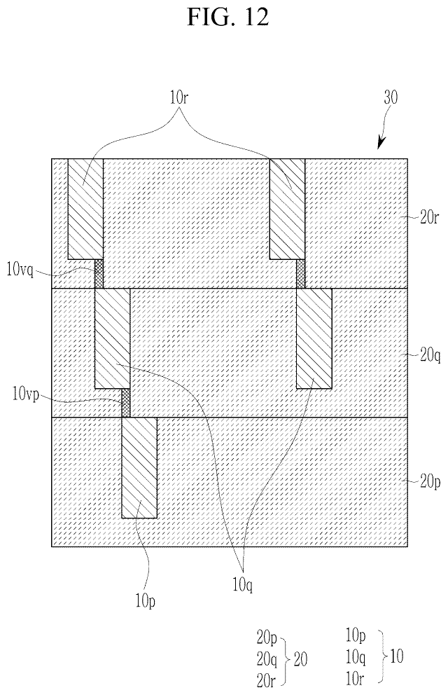

FIG. 12 is a cross-sectional view showing another example of an interconnect structure according to an embodiment.

Referring to FIG. 12, the interconnect structure 30 according to the present example includes a dielectric layer 20 having a trench and a conductive wire 10, like the aforementioned example.

However, the dielectric layer 20 may include a plurality of first, second and third dielectric layers 20p, 20q, and 20r disposed at different heights, and the first, second and third dielectric layers 20p, 20q, and 20r may include the same or different materials. The first, second, and third dielectric layers 20p, 20q, and 20r may each have a trench, and the conductive wire 10 may be embedded in each trench.

The conductive wire 10 may include a plurality of conductive wires 10p, 10q, and 10r disposed at different heights. That is, the conductive wire 10 includes the first conductive wire 10p, the second conductive wire 10q disposed at a different height from the first conductive wire 10p, and the third conductive wire 10r disposed at a different height from the first and second conductive wires 10p and 10q.

Vias electrically connecting the conductive wires 10 are disposed between adjacent conductive wires 10. For example, the vias may include a via 10vp that electrically connects the first conductive wire 10p and the second conductive wire 10q, and a via 10vq that electrically connects the second conductive wire 10q and the third conductive wire 10r. However, the present disclosure is not limited thereto, and may further include another conductive wire disposed at a different height or in a horizontal direction from the first, second and/or third conductive wires 10p, 10q, and 10r and another via electrically connecting a plurality of conductive wires disposed at different heights. The vias 10vp and 10vq may be made of a different conductor than the first, second and third conductive wires 10p, 10q, and 10r, i.e., a different conductor than the aforementioned Mo—W alloy, and may not include the Mo—W alloy.

The first, second and third conductive wires 10p, 10q, and 10r may be the same as the aforementioned conductive wire 10 and may have a line width of less than about 10 nm and include the Mo—W alloy as described above. A specific description of the conductive wire 10 is as described above. The aforementioned anti-scattering layer 40 may be additionally formed on the surfaces of the first, second and third conductive wires 10p, 10q, and 10r. The aforementioned liner 50 may be additionally formed between the first, second and third conductive wires 10p, 10q, and 10r and the dielectric layers 20p, 20q, and 20r.

The aforementioned conductive wire 10 and/or interconnect structure 30 may be included in an integrated circuit device. The integrated circuit device may include DRAM or logic device, but is not limited thereto. The integrated circuit device may include unit devices including, for example, a transistor, a capacitor, a diode, a resistor, or a combination thereof, which are electrically connected to the aforementioned conductive wire 10. The integrated circuit device may be applied to wire (e.g., bit lines, word lines, etc.) that are connected to unit devices such as transistors and/or BEOL (back end of line) structures.

For example, the transistor may have various structures, for example FinFET, GAAFET, MBCFET, CFET, or VFET, but is not limited thereto. For example, the transistor may include a two-dimensional material as the active material and may be a C-FET (complementary field effect transistor), an MBC-FET (multi bridge channel field effect transistor), or a CNT-FET (carbon nanotube field effect transistor), but is not limited thereto.

An example of an integrated circuit device according to an embodiment is described.

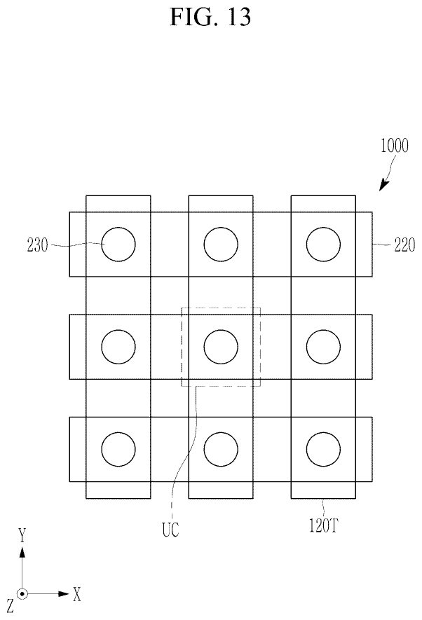

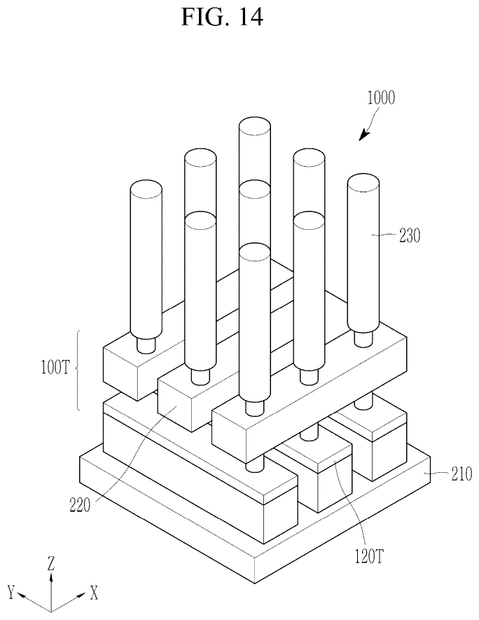

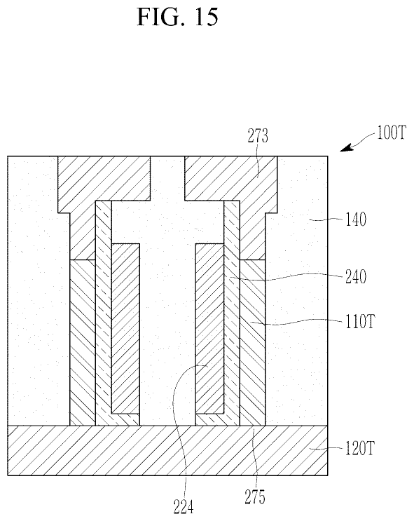

FIG. 13 is a plan view showing an example of an integrated circuit device according to an embodiment, FIG. 14 is a perspective view showing an example of the integrated circuit device of FIG. 13, and FIG. 15 is a schematic view showing an example of a transistor of the integrated circuit device of FIG. 13.

Referring to FIGS. 13 and 14, an integrated circuit device 1000 according to the present embodiment includes a plurality of active regions partitioned by a plurality of bit lines 120T and a plurality of word lines 220, and the plurality of active regions are arranged in an array form. A unit cell UC including a transistor 100T and a capacitor 230 may be disposed in each active region. The integrated circuit device 1000 according to the present embodiment may be a DRAM device.

The integrated circuit device 1000 according to the present embodiment includes a semiconductor substrate 210, a bit line 120T, a word line 220, a transistor 100T, and a capacitor 230.

The semiconductor substrate 210 may include a Group IV semiconductor material such as silicon (Si), germanium (Ge), silicon-germanium (SiGe), and silicon carbide (SiC); a Group III-V semiconductor material such as GaP, GaAs, and GaSb; or a combination thereof. For example, the semiconductor substrate 210 may be a silicon-on-insulator (SOI) substrate or a germanium-on-insulator (GOI) substrate.

The bit line 120T and the word line 220 extend in different directions on the semiconductor substrate 210. For example, the bit line 120T and the word line 220 may be arranged perpendicular to each other. The bit line 120T and the word line 220 may be disposed at different heights from the surface of the semiconductor substrate 210. For example, the bit line 120T may be disposed closer to the surface of the semiconductor substrate 210 than the word line 220.

The bit line 120T and the word line 220 are each electrically connected to a transistor 100T described later. At least one of the bit line 120T and the word line 220 may be the aforementioned conductive wire, and may have a line width of less than about 10 nm and include the Mo—W alloy. For example, each of the bit line 120T and the word line 220 may have a line width of less than about 10 nm and include the Mo—W alloy.

The transistor 100T may be disposed in an active region partitioned by the bit line 120T and the word line 220 on the semiconductor substrate 210, and may be repeatedly arranged along rows and/or columns on the semiconductor substrate 210 to form a transistor array. The transistor 100T may be a vertical channel array transistor (VCAT) in which the transistor channel 110T extends perpendicular to the in-plane direction (e.g., xy direction) of the semiconductor substrate 210. Each transistor 100T may be electrically connected to the bit line 120T, the word line 220, and the capacitor 230 to play a switching role.

Referring to FIG. 15, a transistor 100T according to an example includes a transistor channel 110T, a gate electrode 224, a gate dielectric layer 240, a source electrode 273, and a drain electrode 275. The transistor 100T may be embedded in the dielectric layer 140.

The transistor channel 110T may extend perpendicular to the in-plane direction (e.g., xy direction) of the semiconductor substrate 210 on the semiconductor substrate 210. In this way, the transistor channel 110T is formed perpendicular to the in-plane direction (for example, xy direction) of the semiconductor substrate 210, so that, compared to a structure in which the transistor channel 110T is formed horizontally on the semiconductor substrate 210 or a structure embedded in the semiconductor substrate 210, an area of each unit cell may be effectively reduced and thus more unit cells may be formed on the semiconductor substrate 210. Therefore, a high integration integrated circuit device 1000 may be implemented.

The gate electrode 224 may be electrically connected to the word line 220 and may extend perpendicular to the in-plane direction (e.g., xy direction) of the semiconductor substrate 210. The gate electrode 224 and the transistor channel 110T may face each other with the gate dielectric layer 240 interposed therebetween. The gate electrode 224 may be formed of one or two or more layers.

The gate dielectric layer 240 may be disposed between the gate electrode 224 and the transistor channel 110T and may include a dielectric material. The gate dielectric layer 240 may include, for example, a metal oxide, a semi-metal oxide, a carbon-doped metal oxide, a carbon-doped semi-metal oxide, a metal carbide, a semi-metal carbide, a hydrogenated metal carbide, a hydrogenated semi-metal carbide, a metal nitride, a semi-metal nitride, a carbon-doped metal nitride, a carbon-doped semi-metal nitride, a metal oxynitride, a semi-metal oxynitride, a carbon-doped metal oxynitride, a carbon-doped metal oxynitride, or a combination thereof. The gate dielectric layer 240 may include, for example, AlO_{z} (0<z≤3/2, for example, Al₂O₃), AlN, ZrOₓ (0<x≤2), HfOₓ (0<x≤2), SiO₂, SiCO, SiCN, SiON, SiCOH, AISIO, BN (Boron Nitride), or a combination thereof, but is not limited thereto.

The source electrode 273 and the drain electrode 275 may be disposed at the top and bottom of the transistor channel 110T. The source electrode 273 may be electrically connected to the capacitor 230 and the drain electrode 275 may be electrically connected to the bit line 120T. The drain electrode 275 may be a portion of the bit line 120T.

The capacitor 230 is electrically connected to the source electrode 273 of the transistor 100T and may include electrodes (not shown) facing each other and a dielectric layer (not shown) disposed therebetween. The capacitor 230 may have a cylindrical shape extending perpendicularly to an in-plane direction (e.g., xy direction) of the semiconductor substrate 210, but is not limited thereto.

An example of a DRAM device, which is an integrated circuit device, is described above, but is not limited thereto, and may be applied to all integrated circuit devices including the conductive wire. For example, integrated circuit components may be used for arithmetic operations, program execution, and/or temporary data retention.

The aforementioned conductive wire 10, interconnect structure 30, and/or integrated circuit device 1000 may be included in various electronic devices. The electronic devices may include mobile devices, computers, laptops, tablet PCs, smart watches, sensors, digital cameras, e-books, network devices, vehicle navigation systems, Internet of Things (IoT) devices, Internet of Everything (IoE) devices, drones, door locks, safes, automated teller machines (ATMs), security devices, medical devices, or automotive electrical components, but are not limited thereto.

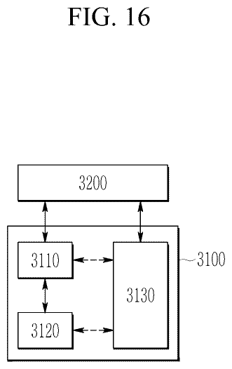

FIG. 16 is a conceptual view showing an example of an electronic device according to an embodiment.

Referring to FIG. 16, an electronic device 3100 according to an embodiment may include a memory unit 3110, an arithmetic logic unit 3120, and a control unit 3130, which may be electrically connected. For example, the memory unit 3110, the arithmetic logic unit 3120, and the control unit 3130 may be implemented as a single integrated circuit device (semiconductor chip), and may be monolithically integrated on a single substrate to be implemented as a single integrated circuit device (semiconductor chip). The memory unit 3110, the arithmetic logic unit 3120, and the control unit 3130 may each independently include a transistor, a capacitor, a diode, a resistor, or a combination thereof. The electronic device 3100 may be connected to one or more input/output devices 3200.

Hereinafter, the embodiments are illustrated in more detail with reference to examples. However, these examples are exemplary, and the scope of claims is not limited thereto.

### Simulation Evaluation

The resistivity of Mo—W alloy wire and copper (Cu) wire according to line width is predicted through simulation.

The evaluation is performed using the Vienna ab initio simulation package (VASP) code (VASP Software GmbH) based on the density functional theory (DFT) to calculate the electronic structure, and the resistivity is calculated using the Boltztrap code (doi: 10.1016/j.cpc.2018.05.010).

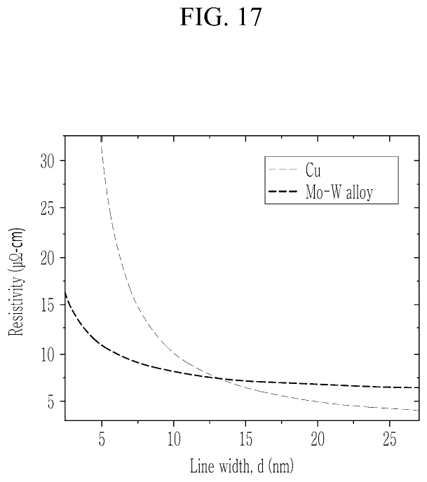

The results are as shown in FIG. 17.

FIG. 17 is a graph showing the resistivity according to the line width of Mo—W alloy wire and Cu wire.

Referring to FIG. 17, the Cu wire exhibits relatively low resistivity at line widths of greater than or equal to about 10 nm, whereas a sharp increase in resistivity occurs at line widths of less than about 10 nm due to the material limitations of copper. In contrast, it may be confirmed that the Mo—W alloy wire shows a small rate of change in resistivity with decreasing line width, and exhibits lower resistivity than Cu wire for line widths less than about 10 nm. From this, it may be expected that Cu may be replaced with a Mo—W alloy as a wire material with a line width of less than about 10 nm.

### Formation of Conductive Wire I

### Example 1-1

A sapphire substrate is placed in the load lock chamber of the sputtering system and transferred to the main chamber of the sputtering system at a pressure of 2×10⁻⁷ Torr. Subsequently, argon gas is flowed into the main chamber at a deposition temperature of less than or equal to 750° C., the total RF power is set to 150 W, and the power ratio of the molybdenum (Mo) target and the tungsten (W) target is adjusted to deposit a Mo—W alloy (Mo: 80 at %, W: 20 at %) on the sapphire substrate. Then, a forming gas annealing (FGA) process is performed in an argon atmosphere at the deposition temperature for 10 minutes to form a Mo—W alloy wire with a line width of about 7 nm.

### Example 1-2

A Mo—W alloy wire with a line width of about 7 nm is formed in the same manner as in Example 1-1, except that the deposition RF power ratio of molybdenum (Mo) and tungsten (W) is changed to form a Mo—W alloy (Mo: 67 at %, W: 33 at %) instead of a Mo—W alloy (Mo: 80 at %, W: 20 at %).

### Example 1-3

A Mo—W alloy wire with a line width of about 7 nm is formed in the same manner as in Example 1-1, except that the deposition RF power ratio of molybdenum (Mo) and tungsten (W) is changed to form a Mo—W alloy (Mo: 50 at %, W: 50 at %) instead of a Mo—W alloy (Mo: 80 at %, W: 20 at %).

### Example 2-1

A Mo—W alloy wire with a line width of about 7 nm is formed in the same manner as in Example 1-1, except that a magnesium oxide (MgO) layer is used instead of the sapphire substrate.

### Example 2-2

A Mo—W alloy wire with a line width of about 7 nm is formed in the same manner as in Example 1-2, except that a magnesium oxide (MgO) layer is used instead of the sapphire substrate.

### Example 2-3

A Mo—W alloy wire with a line width of about 7 nm is formed in the same manner as in Example 1-3, except that a magnesium oxide (MgO) layer is used instead of the sapphire substrate.

### Evaluation I

The crystallinity of the Mo—W alloy wires according to Examples is evaluated.

The crystallinity of Mo—W alloy wires is evaluated by X-ray diffraction (XRD).

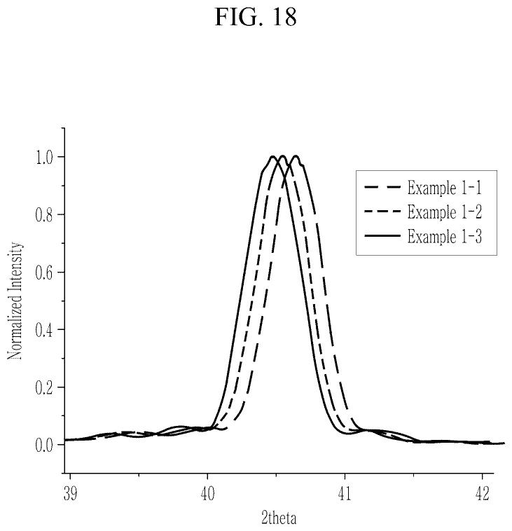

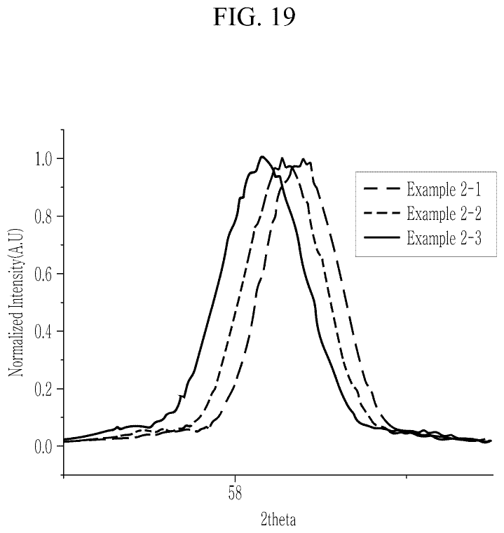

FIG. 18 shows XRD graphs for the Mo—W alloy wires according to Examples 1-1 to 1-3, and FIG. 19 shows XRD graphs for the Mo—W alloy wires according to Examples 2-1 to 2-3.

Referring to FIG. 18, the XRD graphs of the Mo—W alloy wires according to Examples 1-1 to 1-3 show a single peak corresponding to the crystal plane (011) grown on the sapphire substrate, and the single peak shifts in one direction depending on the composition ratio of molybdenum (Mo) and tungsten (W). From this, it may be confirmed that the Mo—W alloy wires according to Examples 1-1 to 1-3 grow as a single crystal without phase separation.

Likewise, referring to FIG. 19, the XRD graphs of the Mo—W alloy wire according to Examples 2-1 to 2-3 show a single peak corresponding to the crystal plane (001) grown on the magnesium oxide (MgO) layer, and it may be confirmed that the single peak moves in one direction depending on the composition ratio of molybdenum (Mo) and tungsten (W). From this, it may be confirmed that the Mo—W alloy wires according to Examples 2-1 to 2-3 grow as a single crystal without phase separation.

### Formation of Conductive Wire II

### Example 3

In a DC magnetron sputtering system with a pressure of 2×10−7 Torr, the DC power is set to 120 watts and 30 watts, respectively, and the molybdenum (Mo) target and tungsten (W) target are pre-sputtered for 10 minutes. Then, the deposition power is adjusted so that molybdenum (Mo) and tungsten (W) are deposited on the substrate at an atomic ratio of 80:20, and a Mo—W alloy (Mo: 80 at %, W: 20 at %) is deposited. Next, a forming gas annealing process (FGA) is performed in an H₂/N₂ (volume ratio of approximately 5:95) atmosphere at 400° C. for 30 minutes to form a Mo—W alloy wire with a line width of about 5 nm.

### Example 4

A Mo—W alloy wire with a line width of about 5 nm is formed in the same manner as in Example 3, except that the deposition power of molybdenum (Mo) and tungsten (W) is changed to deposit a Mo—W alloy (Mo: 13 at %, Ta: 87 at %) instead of a Mo—W alloy (Mo: 80 at %, W: 20 at %).

### Reference Example

A Cu wire with a line width of about 5 nm is formed in the same manner as in Example 3, except that a copper (Cu) target is used instead of the molybdenum (Mo) target and the tungsten (W) target.

### Evaluation II

The resistivity of the Mo—W alloy wires according to Examples and the Cu wire according to Reference Example are evaluated.

Resistivity is calculated as the multiplied value of surface resistance and line width, where surface resistance is measured using a 4-point probe (AIT), and line width is measured using an X-ray reflectometer (X'PERT-PRO MRD) or transmission electron microscope (TEM). It is evaluated as a relative ratio of resistance (R) to maximum resistance value (Rₘₐₓ).

The results are shown in Table 1.

TABLE 1

| | Resistivity (μΩ · cm) |
|---|---|
| Example 3 | 16.61 @ 5.5 nm |
| Example 4 | 20.1 @ 5.1 nm |
| Reference Example | 24.69 @ 5.55 nm |

Referring to Table 1, it may be confirmed that the Mo—W alloy wires according to Examples 3 and 4 have lower resistivity in fine-width wire compared to the Cu wire according to Reference Example. Comparing the Mo—W alloy wires according to Examples 3 and 4, it may be confirmed that the Mo—W alloy wire according to Example 3 has lower resistivity than the Mo—W alloy wire according to Example 4.

From these, it may be expected that the Mo—W alloy wires according to Examples may prevent deterioration of electrical characteristics without a sharp increase in resistance even at a fine line width of less than about 10 nm (less than or equal to about 7 nm).

While the embodiments of the present disclosure have been described in detail, it is to be understood that the disclosure is not limited to the disclosed embodiments, but on the contrary, is intended to cover various modifications and equivalent arrangements included within the spirit and scope of the appended claims.

What is claimed is:

1. A conductive wire, the conductive wire having a line width of equal to or greater than about 1 nanometer (nm) and less than about 10 nm and comprising a molybdenum-tungsten alloy.

2. The conductive wire of claim 1, wherein an aspect ratio of a line thickness to the line width of the conductive wire is greater than or equal to about 3.

3. The conductive wire of claim 1, wherein the molybdenum-tungsten alloy is represented by Mo₁₋ₓWₓ (0<x≤0.99).

4. The conductive wire of claim 1, wherein the tungsten included in the molybdenum-tungsten alloy is included in an amount of greater than 0 atomic percentage (at %) and less than about 50 at % based on a total number of atoms of the molybdenum (Mo) and the tungsten (W) included in the molybdenum-tungsten alloy.

5. The conductive wire of claim 1, wherein a change in resistivity of the conductive wire according to a 10% decrease in the line width is less than about twice.

6. The conductive wire of claim 1, wherein a resistivity of the conductive wire is less than or equal to about 30 microhm-centimeters (μΩ·cm).

7. An integrated circuit device comprising the conductive wire of claim 1.

8. An interconnect structure, comprising
one or more dielectric layers, and
a conductive wire adjacent to the dielectric layers,
wherein a line width of the conductive wire is equal to or greater than about 1 nm and less than about 10 nm, and
the conductive wire comprises a molybdenum-tungsten alloy.

9. The interconnect structure of claim 8, wherein
the dielectric layer defines therein a trench, and
the conductive wire is disposed in the trench.

10. The interconnect structure of claim 8, wherein an aspect ratio of a line thickness to the line width of the conductive wire is greater than or equal to about 3.

11. The interconnect structure of claim 8, wherein the molybdenum-tungsten alloy is represented by Mo₁₋ₓWₓ (0<x≤0.99).

12. The interconnect structure of claim 8, wherein the tungsten included in the molybdenum-tungsten alloy is included in an amount of greater than 0 at % and less than about 50 at % based on a total number of atoms of the molybdenum and the tungsten included in the molybdenum-tungsten alloy.

13. The interconnect structure of claim 8, wherein
a change in a resistivity of the conductive wire according to a 10% decrease in the line width is less than about twice, and
the resistivity of the conductive wire is less than or equal to about 30 μΩ·cm.

14. The interconnect structure of claim 8, wherein the dielectric layer comprises a metal oxide, a semi-metal oxide, a carbon-doped metal oxide, a carbon-doped semi-metal oxide, a metal carbide, a semi-metal carbide, a hydrogenated metal carbide, a hydrogenated semi-metal carbide, a metal nitride, a semi-metal nitride, a carbon-doped metal nitride, a carbon-doped semi-metal nitride, a metal oxynitride, a semi-metal oxynitride, a carbon-doped metal oxynitride, a carbon-doped semi-metal oxynitride, or a combination thereof.

15. The interconnect structure of claim 8, wherein the conductive wire and the dielectric layer are in contact with each other.

16. The interconnect structure of claim 8, further comprising an anti-scattering layer disposed on an upper portion of the conductive wire.

17. The interconnect structure of claim 8, further comprising a liner between the dielectric layer and the conductive wire,
wherein the liner comprises tungsten or a tungsten alloy, excluding a molybdenum-tungsten alloy.

18. The interconnect structure of claim 8, wherein
the dielectric layer comprises a first dielectric layer and a second dielectric layer positioned at different heights, and
the conductive wire comprises
a first conductive wire disposed in a trench defined in the first dielectric layer, and
a second conductive wire disposed in a trench defined in the second dielectric layer.

19. An integrated circuit device comprising the interconnect structure of claim 8.

20. The integrated circuit device of claim 19, further comprising a transistor, a capacitor, a diode, a resistor, or a combination thereof, electrically connected to the conductive wire.
